(19) United States
(12) Patent Application Publication
(10) Pub. No.: US 2005/0205126 A1
(43) Pub. Date: Sep. 22, 2005

(54) Photovoltaic conversion device, its manufacturing method and solar energy system

(75) Inventors: Hiroki Okui, Higashiomi-shi (JP); Yoji Seki, Higashiomi-shi (JP); Yoshio Miura, Higashiomi-shi (JP); Hisao Arimune, Higashiomi-shi (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/084,844

(22) Filed: Mar. 18, 2005

(30) Foreign Application Priority Data
Mar. 22, 2004 (JP) 2004-083513

(51) Int. Cl. H01L 25/00

(52) U.S. Cl. 136/250; 438/63

(57) ABSTRACT

A photovoltaic conversion device has a substrate 1 as a lower electrode having a first region 31 and a second region 32 adjacent to the first region, a lot of semiconductor particles 20 joined to the first region 31, an insulator 4 formed between the semiconductor particles 20 on the substrate 1 in the first region 31 and on the substrate 1 in the second region 32, a transparent conductive layer 5 as an upper electrode formed so as to cover the upper part of the semiconductor particles 20 in the first region 31 and the insulator 4 in the first region 31, and a collecting electrode formed of a finger electrode 15 arranged on the transparent conductive layer 5 in the first region 31 and a bus bar electrode 16 which is arranged in the second region 32 and connected to the finger electrode 15. By making the thickness of the insulator 4 in the second region 32 larger than that of the insulator 4 in the first region, even if generated photocurrents concentrate on the bus bar electrode 16, insulating properties between the substrate 1 and the transparent conductive layer 5 can be ensured stably, thereby to achieve high photovoltaic conversion efficiency.

### BACKGROUND OF THE INVENTION

1. Field of the Invention

The present invention relates to a photovoltaic conversion device used for photovoltaic power generation and the like, its manufacturing method and a solar energy system. The present invention relates to, in particular, a photovoltaic conversion device using semiconductor particles, its manufacturing method and a solar energy system.

2. Description of Related Art

An example of a conventionally proposed photovoltaic conversion device using semiconductor particles is shown in a sectional view of FIG. 3.

As shown in FIG. 3, in the photovoltaic conversion device, a low-melting-point metal layer 108 is formed on a substrate 101 used as a lower electrode, a lot of one conduction-type semiconductor particles 103 are fixed to the low-melting-point metal layer 108 to be buried therein and an insulating layer 102 is formed so as to cover the fixed semiconductor particles 103 and the low-melting-point metal layer 108. The one conduction-type semiconductor particles 103 is made to be exposed by grinding. Subsequently, an other conduction-type semiconductor 104 and a transparent conductive layer 105 used as an upper electrode are formed so as to cover the exposed one conduction-type semiconductor particles and the insulating layer 102 in sequence (Refer to Japanese Unexamined Patent Publication No. 04-207085).

In the above-mentioned photovoltaic conversion device, since generated photocurrents concentrate on, especially, an area where a collecting electrode for collecting photocurrents is arranged, it is necessary to separate the other conduction-type semiconductor 104 from the low-melting-point metal layer 108 by using the insulator 102 for sure.

However, since the one conduction-type semiconductor particles are made to be exposed by grinding in the photovoltaic conversion device shown in FIG. 3, the grinding may lead to a defect such as a hole in the insulating layer 2 or peeling from the low-melting-point metal layer 108.

Generated photocurrents concentrate on, especially, the area where the collecting electrode for collecting photocurrents is arranged. Accordingly, when the insulating layer 102 is made thin or becomes too small due to grinding, there is a problem that electric field concentrates on the insulating layer 102 in the arrangement area of the collecting electrode and therefore insulation between the other conduction-type semiconductor 104 and the low-melting-point metal layer 108 cannot be ensured. This further causes a problem that a short-circuit occurs between the other conduction-type semiconductor 104 and the low-melting-point metal layer 108, thereby to reduce photovoltaic conversion efficiency.

An object of the present invention is to provide a photovoltaic conversion device having high photovoltaic conversion efficiency, its manufacturing method and a solar energy system using the photovoltaic conversion device while preventing a short-circuit in the photovoltaic conversion device.

### SUMMARY OF THE INVENTION

A photovoltaic conversion device of the present invention is characterized by that is comprises a substrate as a lower electrode having a first region and a second region adjacent to the first region, a lot of semiconductor particles joined to the first region, an insulator formed between the semiconductor particles on the substrate in the first region and on the substrate in the second region, a transparent conductive layer as an upper electrode formed so as to cover the upper part of the semiconductor particles in the first region and the insulator in the first region, and a collecting electrode formed of finger electrodes arranged on the transparent conductive layer in the first region and a bus bar electrode which is arranged in the second region and connected to the finger electrodes, and the thickness of the insulator in the second region is substantially larger than that of the insulator in the first region.

In the photovoltaic conversion device of the present invention, since the thickness of the insulator in the second region is basically larger than that of the insulator in the first region, even if photocurrents generated through photovoltaic conversion are collected by the finger electrodes and concentrate on the bus bar electrode, insulating properties between the transparent conductive layer used as the upper electrode and the substrate used as the lower electrode can be ensured stably. This can prevent a short-circuit current from occurring. As a result, the photovoltaic conversion device having high photovoltaic conversion efficiency can be produced.

The photovoltaic conversion device of the present invention is characterized by further comprising a conductive protection layer formed in the surface of the semiconductor particles.

With this configuration, photocurrents can reach the transparent conductive layer as the upper electrode from the generation place through the conductive protection layer. For this reason, the resistance to the photocurrents leading to the transparent conductive layer is decreased, thereby to reduce resistance loss in the photocurrents. As a result, the photovoltaic conversion device having high photovoltaic conversion efficiency can be produced.

It is preferred that the insulator in the first region becomes thinner as the insulator is away from the second region increases.

With this configuration, since the thickness of the insulator in the first region does not change discontinuously, the insulating properties of the insulator in the first region can be ensured stably. This can prevent a short-circuit current from occurring in the first region. As a result, the photovoltaic conversion device having high photovoltaic conversion efficiency can be produced.

It is preferred that the second region is adjacent to both sides of the first region, the insulator in the first region has a curved surface that becomes depressed substantially in the shape of a concave in the upper part thereof and the most depressed portion of the curved surface in the first region is located at the center between a one side adjoining part where the first region is adjacent to one second region and an other side adjoining part where the first region is adjacent to the other second region.

With this configuration, the insulator is formed to have the smallest thickness at the center of the first region. Therefore, at the center of the first region, loss in the amount of light led to the pn junctions of the semiconductor particles can be minimized. Since the amount of the used insulator is reduced at the center of the first region, productivity of the photovoltaic conversion device can be improved.

It is preferred that the thickness of the insulator in the first region is 1 μm or more at the thinnest portion.

With this configuration, in the insulator in the first region, insulating properties between the substrate and the transparent conductive layer can be ensured stably.

Further, it is preferred that the thickness of the insulator in the second region is 5 μm or more.

With this configuration, insulating properties of the insulator in the second region can be ensured stably.

It is preferred that the transparent conductive layer is formed from a material with a high optical transmittance of 70% or more ranging from 400 to 1200 nm of wavelength.

This property results in reduction in loss of the amount of light led to the pn junctions of the semiconductor particles.

It is preferred that the conductive protection layer runs along the convex curved surface of the semiconductor particles.

With this configuration, carriers generated inside the semiconductor particles can be efficiently collected along the convex curved surface of the semiconductor particles.

A manufacturing method of the photovoltaic conversion device of the present invention is characterized by that it includes steps of preparing a substrate as a lower electrode having a first region and a second region adjacent to the first region and joining a lot of semiconductor particles to the substrate in the first region, forming an insulator between the semiconductor particles on the substrate in the first region and on the substrate in the second region, forming a transparent conductive layer as an upper electrode formed so as to cover the upper part of the semiconductor particles in the first region and the insulator in the first region, and forming finger electrodes on the transparent conductive layer in the first region and a bus bar electrode connected to the finger electrodes in the second region, and in the step of forming the insulator, the thickness of the insulator in the first region is basically formed to be smaller than that of the insulator in the second region.

By forming the insulator in the first region to be thin in this manner, light entering into the photovoltaic conversion device is urged to be reflected on the substrate, thereby to obtain high photovoltaic conversion efficiency.

A conductive protection layer may be formed on the surface of the semiconductor particles following the step of joining the semiconductor particles.

In the step of joining the semiconductor particles, it is preferred that the substrate and the semiconductor particles are heated while a certain amount of weight is applied to the semiconductor particles.

In the step of joining the semiconductor particles, the substrate and the semiconductor particles are heated entirely while a certain amount of load is applied. Accordingly, when the semiconductor particles include a p-type impurity, for example, the p-type impurity diffuses in the vicinity of the junctions between the semiconductor particles and the substrate to form a p⁺ layer, thereby to achieve BSF (Back Surface Field) effect. As a result, the photovoltaic conversion device having high photovoltaic conversion efficiency can be produced.

Preferably, in the step of forming the insulator, to ensure the thickness of the insulator, it is preferred that the insulator is formed by using an insulator-forming solution with a concentration of solid content of 10 percent or more by mass.

The solar energy system of the present invention using the photovoltaic conversion device as a power generating means is characterized by that it is configured so as to supply electric power generated by the power generating means to a load.

By using the photovoltaic conversion device having high photovoltaic conversion efficiency of the present invention, optical power generation with high photovoltaic conversion efficiency can be performed.

The above-mentioned and other advantages, features and effects will appear more fully hereinafter from a consideration of the following description with reference to the accompanying drawings.

### BRIEF DESCRIPTION OF THE DRAWINGS

FIG. 1(a) is a plan view showing a photovoltaic conversion device in accordance with an embodiment of the present invention and FIG. 1(b) is a principal part sectional view of the photovoltaic conversion device.

FIG. 2 is a principal part sectional view showing the photovoltaic conversion device in accordance with another embodiment of the present invention.

FIG. 3 is a sectional view showing a conventional photovoltaic conversion device.

### DETAILED DESCRIPTION OF PREFERRED EMBODIMENTS

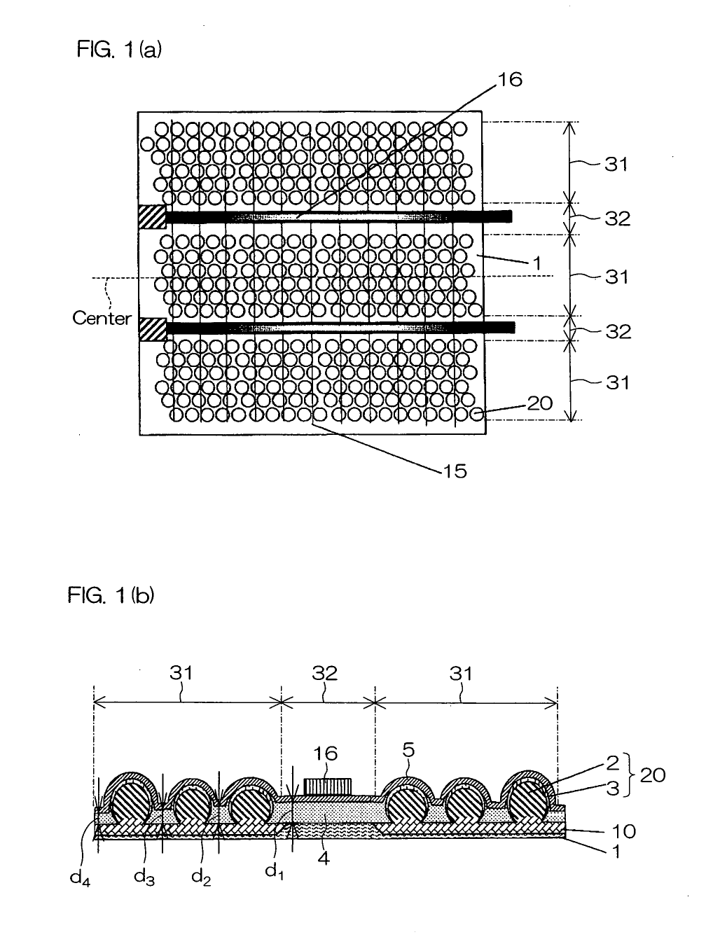

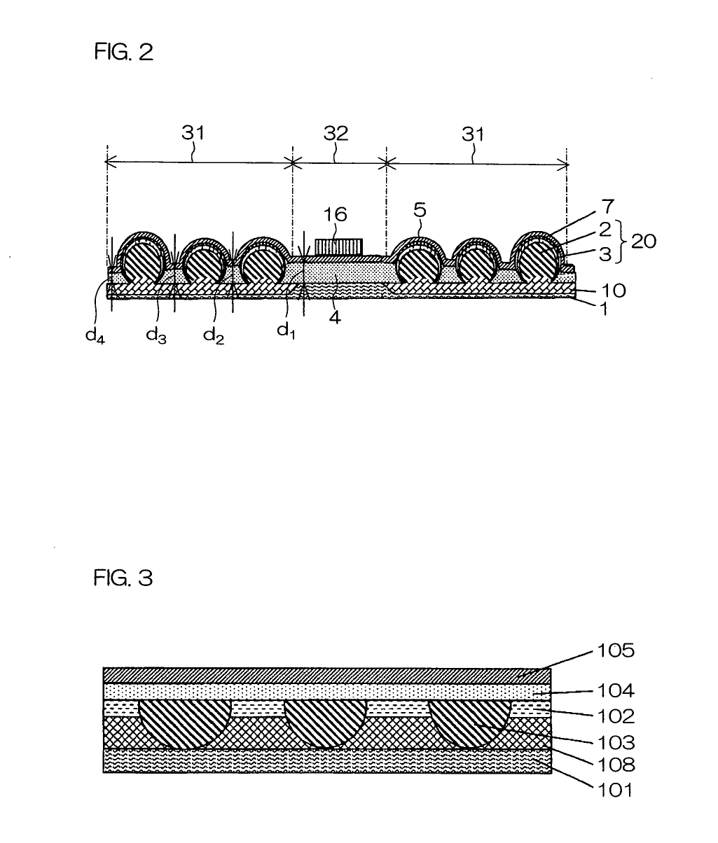

An embodiment of a photovoltaic conversion device is described in detail with reference to FIGS. 1(a) and 1(b) and FIG. 2.

FIGS. 1(a) and 1(b) are a plan view and a principal part sectional view showing the photovoltaic conversion device in accordance with the embodiment of the present invention, respectively. FIGS. 1(a) and 1(b) show a substrate 1, one conduction-type crystal semiconductor particles 2, another reverse conduction-type semiconductor 3, an insulator 4, a transparent conductive layer 5, an alloy layer 10 formed on the substrate 1, finger electrodes 15, bus bar electrodes 16, semiconductor particles 20, first region 31 and second regions 32. A dotted line in FIG. 1(a) represents a center of the first region 31.

This photovoltaic conversion device has the substrate 1 as a lower electrode including the first regions 31 and the second regions 32 adjacent to the first region 31, a lot of semiconductor particles 20 joined to the first regions 31, the insulator 4 formed between the semiconductor particles 20 on the substrate 1 in the first regions 31 and on the substrate 1 in the second regions 32, the transparent conductive layer 5 as an upper electrode formed so as to cover the upper part of the semiconductor particles 20 in the first regions 31, at least the insulator 4 in the first regions 31, and a collecting electrode comprised of the finger electrodes 15 arranged on the transparent conductive layer 5 in the first region 31 and the bus bar electrodes 16 which are arranged in the second regions 2 and connected to the finger electrodes 15.

The substrate 1 is a plate-like body made from a metal, or ceramics, glass or the like, to which a metal is adhered on its surface. Such metal includes aluminum (Al), aluminum alloy andiron (Fe). Such ceramics include alumina ceramics. Quartz, to which a metal is adhered, may be used for the substrate 1.

The semiconductor particles 20 perform photovoltaic conversion and are obtained by forming the other conduction-type semiconductor layer 3 on the surface of the one conduction-type crystal semiconductor particles 2 except a part thereof.

The crystal semiconductor particles 2 are made from silicone (Si), germanium (Ge), etc.

The crystal semiconductor particles 2 may employ a p-type impurity such as boron (B), aluminum and gallium (Ga) or an n-type impurity such as phosphorus (P) and arsenic (As), which is added thereto as an impurity. When the substrate 1 is formed of aluminum, the crystal semiconductor particles 2 is preferably p-type particles made from silicon. Since aluminum spreads in the vicinity of junctions between the substrate 1 and the crystal semiconductor particles 2 to form a p⁺ layer when the crystal semiconductor particles 2 are made from silicon, the photovoltaic conversion device which has high photovoltaic conversion efficiency due to BSF (Back Surface Field) effect can be obtained.

The semiconductor layer 3 is a reverse conduction-type conductor to the crystal semiconductor particles 2 and is obtained by adding a minor constituent to silicon or the like. The concentration of the minor constituent may be about 1×10¹⁶ to 10¹⁹ atoms/cm³, for example. The film quality of the semiconductor layer 3 may be any of crystalline, amorphous or mixture of crystalline and amorphous. In view of optical transmittance, the mixture of crystalline and amorphous is preferable.

The insulator 4 is formed from an insulating material for electrical isolation between the substrate 1 and the transparent conductive layer 5. The insulator 4 may employ a heat-resistant polymer material, for example. Polyimide resin, phenol resin, silicone resin, epoxy resin, polycarbosilane resin and the like can be used as the heat-resistant polymer material. Preferably, polyimide resin is used from the viewpoint of chemical resistance or heat resistance.

The transparent conductive layer 5 is formed from a material with a high optical transmittance ranging from 400 to 1200 nm of wavelength. When the optical transmittance of the transparent conductive layer 5 falls within the above-mentioned range, the transparent conductive layer 5 can be prevented from absorbing light. The transparent conductive layer 5 is formed from one or more types of films of oxide selected from SnO₂, In₂O₃, Indium Tin Oxide (ITO), ZnO, TiO₂ and the like, or one or more types of films of metal selected from titanium (Ti), platinum (Pt), gold (Au) and the like.

The finger electrodes 15 and the bus bar electrodes 16 are formed from a conductive material such as silver paste.

As shown in FIG. 1(b), in the photovoltaic conversion device, a lot of semiconductor particles 20 are joined to the substrate 1 in the first regions 31.

On the substrate 1 in the first regions 31, the alloy layer 10 comprised of the substrate 1 and the crystal semiconductor particles 2 is formed.

The semiconductor particle 20 is comprised of the one conduction-type (for example, p-type) crystal semiconductor particle 2 and the other conduction-type (for example, n-type) semiconductor layer 3 formed on the surface of the crystal semiconductor particle 2.

The crystal semiconductor particles 2 are shaped like a polyhedron, a polyhedron without sharp corners, a ball or an oval. Since dependency of light on beam angle can be made smaller, the crystal semiconductor particles 2 preferably have a convex curved surface. The particle diameter of the crystal semiconductor particles 2 may be either uniform or ununiform. When the particle diameter is uniform, however, the process of making the particle diameter uniform is required. For this reason, ununiform particle diameter is more advantageous in order to increase productivity. The particle diameter of the crystal semiconductor particles 2 is preferably 0.2 to 1.0 mm, and more preferably, 0.2 to 0.6 mm. When the particle diameter of the crystal semiconductor particles 2 exceeds 1.0 mm, the photovoltaic conversion device requires the same amount of raw material as a conventional crystal board type photovoltaic conversion device including a cut part and hence, the advantage of using the crystal semiconductor particles 2 is lost. On the other hand, when the particle diameter of the crystal semiconductor particles 2 is less than 0.2 mm, it becomes difficult to arrange and join the crystal semiconductor particles 2 to the substrate 1.

In the semiconductor particle 20, the semiconductor layer 3 is formed on the surface of the crystal semiconductor particle 2 except a portion thereof. Preferably, the semiconductor layer 3 is formed up to the vicinity of the junctions between the crystal semiconductor particles 2 and the substrate 1 along the curved surface of the crystal semiconductor particles 2. By forming the semiconductor layer 3 up to the vicinity of the junctions between the crystal semiconductor particles 2 and the substrate 1 along the curved surface of the crystal semiconductor particles 2, a large area of pn junction can be taken and carriers generated inside the crystal semiconductor particles 2 can be collected efficiently.

A part of crystal semiconductor particle 2 consists of a minimum junction required to join the substrate 1 surely and a minimum necessary separation part required to separate the substrate 1 from the semiconductor layer 3. For this reason, in the photovoltaic conversion device shown in FIG. 1(b), the semiconductor layer 3 is formed up to the vicinity of the junctions between the lower half part of the crystal semiconductor particles 2 and the substrate 1 with being separated from the substrate 1.

The first region 31 means the region where a lot of semiconductor particles 20 are joined to the substrate 1 in the photovoltaic conversion device and the second region 32 means the region adjacent to the first region 31 where the bus bar 16 is arranged on the substrate 1 in the photovoltaic conversion device.

The insulator 4 is formed between the semiconductor particles 20 in the first regions 31 and on the substrate 1 in the second regions 32. The insulator 4 allows the upper part of the semiconductor layer 3 of the semiconductor particle 2 to be exposed while covering the lower part of semiconductor layer 3.

The insulator 4 is formed so that its thickness in the second regions 32 is basically larger than that in the first regions 31. That is, a thickness d1 in the second regions 32 is larger than thicknesses d2, d3 and d4 in the first regions 31. The thickness of the insulator 4 is formed so that the semiconductor particles 20 can perform photovoltaic conversion and the upper part of semiconductor particles 20 is exposed. It is preferred that the insulator 4 in the first regions 31 becomes thinner as the insulator 4 is away from the second region 32. That is, as shown in FIG. 1(b), in the insulator 4, d2 is smaller than d1, d3 is smaller than d2, and d4 is smaller than d3.

Although not shown, when the insulator 4 in the first region 31 has a curved surface that becomes depressed substantially in the shape of a concave in its upper part, it is preferred that the most depressed portion of the curved surface is located at the center between a one side adjoining part where the first region 31 is adjacent to one second region 32 and an other side adjoining part where the first region 31 is adjacent to the other second region 32. That is, it is preferred that the thinnest portion of the first region 31 is located at the center of the first region 31 shown by the dotted line of FIG. 1(a).

By making the thickness of the insulator 4 in the second regions 32 larger than that of the insulator 4 in the first regions 31 in this manner, when the finger electrodes 15 are formed on the insulator 4 in the second regions 32, even if photocurrents concentrate and more load is applied thereto compared with other parts, insulation properties between the transparent conductive layer 5 and the substrates 1 can be maintained stably and therefore a short-circuit therebetween can be prevented. On the other hand, by making the insulator 4 thin in the first region 31, loss in the amount of light led to the pn junctions can be reduced and also the amount of the insulator 4 becomes smaller. This results in high productivity of the photovoltaic conversion device.

It is preferred that the thickness of the insulator 4 is 1 μm or more at the thinnest portion. The thickness of the insulator 4 of less than 1 μm is undesirable as it leads to unstable insulation properties between the substrate 1 and the transparent conductive layer 5.

Further, it is preferred that the thickness of the insulator 4 in the second regions 32 where the finger electrodes 15 are arranged is 5 μm or more.

The thickness of the insulator 4 in the second region 32 of less than 5 μm is undesirable as it leads to unstable insulation properties of the insulator 4 in the second region 32.

Although the insulator 4 is formed so as to cover the lower half part of the semiconductor layer 3 in the photovoltaic conversion device shown in FIG. 1(b), the insulator 4 may be formed so as to cover only the surface of the crystal semiconductor particle 2, on which the semiconductor layer 3 is not formed.

The transparent conductive layer 5 is formed so as to cover the upper part of the semiconductor particles 20 in the first regions 31 and the insulator 4 in the first regions 31. The semiconductor particles 20 are electrically joined to each other through the transparent conductive layer 5 and the photocurrents generated in each semiconductor particle 20 can be collected with the finger electrodes 15 formed on the transparent conductive layer 5 through the transparent conductive layer 5.

Preferably, the transparent conductive layer 5 is covered to the upper part of the semiconductor layer 3 and the insulator 4 in the first regions 31 and the second regions 32 so that the process of providing the portion where the transparent conductive layer 5 is not formed becomes unnecessary, thereby to simplify the manufacturing process.

The transparent conductive layer 5 can also serve as an antireflection film by selecting the film thickness appropriately. Further, it is preferred that the transparent conductive layer 5 is formed along the surface of the semiconductor layer 3 or the crystal semiconductor particles 2, and along the convex curved surface of the crystal semiconductor particles 2. By forming the transparent conductive layer 5 along the convex curved surface of the semiconductor particles 2, it becomes possible to efficiently collect the carriers generated within the crystal semiconductor particles 2.

By use of the transparent conductive layer 5, part of incident light irradiated on the area where no semiconductor particle 20 exists passes through the transparent conductive layer 5, is reflected on the substrate 1 as a lower electrode and then irradiated to the pn junctions of the semiconductor particles 20. As a result, the light irradiated to the whole photovoltaic conversion device can be efficiently irradiated to the semiconductor particles 20.

In this photovoltaic conversion device, the collecting electrode is formed and the collecting electrode consists of the finger electrodes 15 and the bus bar electrodes 16.

The finger electrodes 15 each are arranged on the transparent conductive layer 5 all over the whole surface of the first regions 31 and connected to the bus bar electrode 16. Preferably, the finger electrodes 15 are arranged so as to extend away from the second region 32.

The finger electrodes 15 are arranged so as to be orthogonal to the bus bar electrode 16 and parallel to each other in order to lower a serial resistance value of the finger electrodes 15.

In the adjacent second regions 32 where the semiconductor particle 20 is not formed, the bus bar electrode 16 is arranged in the longitudinal direction of the second region 32. Since the second regions 32 are areas which do not contribute to photovoltaic conversion originally, shadow loss can be removed. Since the finger electrodes 15 are formed to be long and narrow and arranged on the transparent conductive layer 5 so as to extend from the bus bar electrode 16 toward the first region 31, shadow loss in the semiconductor particles 20 can be reduced. The shadow loss means that incident light is interrupted with the electrodes at a light-receiving surface side and dead space due to shadow occurs.

Since the bus bar electrode 16 is not arranged in the first regions 31 but in the second regions 32, it is formed on a flatter part compared with the case where it is formed on the transparent conductive layer 5 having a convex curved surface along the semiconductor particles 20. As a result, since the bus bar electrode 16 can be formed so that there occurs no any fault such as gap between the finger electrodes 15 and the transparent conductive layer 5, contact resistance can be reduced and adhesiveness between the finger electrodes 15 and the transparent conductive layer 5 can be improved.

With such arrangement of the finger electrodes 15 and the bus bar electrodes 16, it is possible to collect the photocurrents generated in the semiconductor particles 20 with the finger electrodes 15 and then collect the photocurrents collected by the finger electrodes 15 with the bus bar electrodes 16.

Since the insulator 4 in the second regions 32 where the bus bar electrode 16 is arranged is thick, even if the photocurrents concentrate on the bus bar electrode 16, occurrence of a short-circuit current that flows from the transparent conductive layer 5 contacting the bus bar electrode 16 to the substrate 1 through the insulator 4 and deterioration of the insulator 4 due to heat generated by the bus bar electrode 16 can be prevented. This ensures insulating properties.

In the photovoltaic conversion device of this embodiment, as shown FIG. 1(a), the second regions 32 are linearly formed long and narrow and bus bar electrodes 16 are also formed linearly accordingly. However, the shape of the bus bar electrodes 16 is not restricted specifically. When the second regions 32 are shaped in a curved manner, the bus bar electrodes 16 may be also shaped in a curve. Although the bus bar electrodes 16 and the finger electrodes 15 cross at right angles and a plurality of the finger electrodes 15 are arranged in parallel to each other in the photovoltaic conversion device shown in FIG. 1(a), the angle which the bus bar electrode 16 forms with the finger electrodes 15 can be designed appropriately.

A protection layer (not shown) may be formed on the transparent conductive layer 5 on which the bus bar electrodes 16 and finger electrodes 15 are formed.

Such protection layer should have characteristics of a transparent dielectric. For example, one or more of the constituents: silicon oxide, cesium oxide, aluminum oxide, silicon nitride, titanium oxide, SiO₂—TiO₂, tantalum pentoxide, yttrium oxide, etc. is/are formed on the transparent conductive layer 5 in a monolayer or multilayer. Since the above-mentioned protection layer is provided in an entrance plane of light, translucency is required. Further, to prevent leak between the transparent conductive layer 5 and the exterior, the protection layer needs to be a dielectric. The protection layer can attain functions of an antireflection film by setting its film thickness appropriately.

Next, one embodiment of a manufacturing method of the photovoltaic conversion device of the present invention will be described with reference to the photovoltaic conversion device shown in FIG. 1(a) and FIG. 1(b).

The manufacturing method of this photovoltaic conversion device includes a process of joining a lot of semiconductor particles 20 to the substrate 1 as a lower electrode in the first regions 31.

Firstly, the substrate 1 as a lower electrode is prepared. Subsequently, a lot of crystal semiconductor particles 2 are closely placed on the prepared substrate 1 in a plurality of regions in a monolayer. In this case, a jig is previously placed on the substrate 1 in the second regions 32 and then the crystal semiconductor particles 2 are arranged on the substrate 1. Accordingly, the crystal semiconductor particles 2 can be arranged in the first regions 31 except the second regions 32. Subsequently, the substrate 1 and the crystal semiconductor particles 2 are entirely heated while a certain amount of load is applied to the crystal semiconductor particles 2. In this manner, the substrate 1 is joined to the crystal semiconductor particles 2 via the alloy layer 10 of the substrate 1. The substrate 1 and the crystal semiconductor particles 2 may be joined to each other as follows: the semiconductor layer 3 is formed on the crystal semiconductor particles 2, that is, the semiconductor particles 20 are formed and then the substrate 1 and the semiconductor particles 20 are entirely heated while a certain amount of load is applied to the crystal semiconductor particles 2. When the substrate 1 formed from aluminum is joined to the crystal semiconductor particles 2 formed from silicon, for example, to increase bonding strength, heating temperature is set to be 577° C. as an eutectic temperature of aluminum and silicon or more.

More specifically, for example, the semiconductor layer 3 may be formed on the crystal semiconductor particles 2 by introducing a small amount of phosphorus compound as n-type impurity in gaseous phase or boron compound as p-type impurity in gaseous phase into silane compound in gaseous phase according to vapor deposition or the like. Alternatively, the semiconductor layer 3 may be formed on the crystal semiconductor particles 2 according to ion plantation method, thermal diffusion method or the like.

In this manner, the semiconductor layer 3 is formed prior to formation of the insulator 4. Since the semiconductor layer 3 is thus formed prior to formation of the insulator 4, the insulator 4 does not adhere to the surface of crystal semiconductor particles 2. Therefore, high-quality pn junction can be formed. Further, since the semiconductor layer 3 can be formed also in the lower half part of the crystal semiconductor particles 2, area of the pn junctions can be increased, thereby to improve photovoltaic conversion efficiency.

Although the semiconductor layer 3 is formed along the convex curved surface of the crystal semiconductor particles 2 prior to formation of the insulator 4 in the photovoltaic conversion device shown in FIG. 1(b), the semiconductor layer 3 may be formed so as to cover the upper part of the crystal semiconductor particles 2 exposed from the insulator 4, or the upper part of the crystal semiconductor particles 2 and the insulator 4 after formation of the insulator 4.

In the semiconductor particle 20, when the crystal semiconductor particles 2 are p-type, the semiconductor layer 3 is formed to become n-type, and when the crystal semiconductor particles 2 are n-type, the semiconductor layer 3 is formed to become p-type. The semiconductor layer 3 may be formed by pouring a dopant into the outline of the crystal semiconductor particles 2 rather than may be formed on the crystal semiconductor particles 2. Alternatively, It is possible that the semiconductor layer 3 is formed by thermal diffusion of the dopant to the crystal semiconductor particles 2 and then the substrate 1 is joined to the crystal semiconductor particles 2.

Here, the semiconductor layer 3 and substrate 1 must be separated electrically. To separate the semiconductor layer 3 from the substrate 1, when the semiconductor layer 3 is formed, an area where the semiconductor layer 3 is not formed may be provided in the perimeter of the junctions between the substrate 1 and the crystal semiconductor particles 2 with a mask. Alternatively, after the semiconductor layer 3 is formed all over the surface of the crystal semiconductor particles 2, the semiconductor layer 3 in the perimeter of the junction with the substrate 1 may be removed by etching.

The manufacturing method of this photovoltaic conversion device includes a process of forming the insulator 4 between the semiconductor particles 20 in the first regions 31 and on the substrate 1 in the second regions 32.

The insulator 4 is formed by being filled between the semiconductor particles 20 so that its thickness in the first regions 31 is smaller than that in the second regions 32. The insulator 4 is filled according to various methods including a dipping method, a spin coat method, a spray method, a screen printing method, a method of using capillarity, etc.

The method of using capillarity is carried out as follows: An insulator-forming solution for forming the insulator 4 is supplied on the substrate 1 from the second region 32 toward the center of the first region 31. Then, the insulator-forming solution automatically moves and spreads so as to fill gaps between a lot of semiconductor particles 20 according to capillarity, thereby to be filled on the substrate 1 and the gaps between the semiconductor particles 20. The insulator 4 thus formed is subjected to heating and hardened. This method is preferable since the insulator 4 can be formed without using a large-sized device. Further, since the below-mentioned viscosity of the insulator-forming solution is utilized in filling the insulator 4 between the semiconductor particles 20 according to the method of using capillarity, the thickness in the second regions 32 can be automatically and readily made smaller than the thickness in the first regions 31 without requiring any special processing.

The case of forming the insulator 4 formed from polyimide resin according to the method of using capillarity will be described below. Firstly, uncured polyimide resin is melted in an organic solvent to prepare an insulator-forming solution. The organic solvent may employ N-methylpyrolidone, N,N′-dimethylformamide, N,N′-dimethylacetamide, o-methyl phenol, m-methyl phenol, p-methyl phenol, or the like. Preferably, N-methylpyrolidone or N,N′-dimethylacetamide is used because of their high solubility and low toxicity. Subsequently, an adjusted amount of the insulator-forming solution thus prepared is supplied on the substrate 1 in the plurality of second regions 32 using a dispenser, for example. The upper part of the semiconductor particles 20 can be exposed without being covered with the insulator 4 by adjusting the amount supplied of the insulator-forming solution depending on the area of the second region 32 and the like. The below-mentioned viscosity of the insulator-forming solution allows the insulator-forming solution to automatically become thicker in the second regions 32 on which the insulator-forming solution is applied firstly without requiring any special processing.

Then, the insulator-forming solution on the substrate 1 in the second regions 32 is moved so as to gradually go away from the second region 32 according to capillarity and finally immerses the whole area between the adjacent semiconductor particles 20 on the substrate 1. To form the insulator 4 while maintaining high productivity of the photovoltaic conversion device by facilitating movement of the insulator-forming solution according to capillarity, in the case of 10 percent by mass of solid content, an upper limit of the viscosity of the insulator-forming solution at 25° C. is set to be 100 mPa-s, preferably 60 mPa-s and more preferably 40 mPa-s. When the viscosity exceeds the above-mentioned range, the viscosity can increase during filling of the insulator-forming solution, thereby to stop the filling. When the viscosity of the insulator-forming solution is 60 mPa-s or less, since the insulator-forming solution can move extensively according to capillarity, the amount of the insulator-forming solution supplied to the second regions 32 can be reduced. This leads to high productivity of the photovoltaic conversion device. When the viscosity is 40 mPa-s or less, the insulator-forming solution can be quickly filled toward the lower part between the semiconductor particles 20 and the consumed amount of the insulator-forming solution as a raw material of the insulator 4 can be reduced up to the necessary minimum.

In the case of 10 percent by mass of solid content, a lower limit of the viscosity of the insulator-forming solution at 25° C. is set to be 5 mPa-s, preferably 10 mPa-s. When the viscosity of the insulator-forming solution is smaller than the above-mentioned lower limit, the insulator-forming solution moves between the semiconductor particles 20 in the first regions 31 at an extremely fast speed without being subject to viscosity resistance. Accordingly, since it becomes difficult to adjust the thickness of the insulator 4, the viscosity is undesirable.

Once the insulator 4 is applied, the viscosity is increased with the passage of time. Therefore, the insulator 4 spread once does not run further even if time passes.

In the above-mentioned filling of the insulator-forming solution, once the insulator-forming solution is applied on the substrate 1 with uniform thickness by utilizing capillarity, film thickness may be adjusted so that the thickness in the second regions 32 is larger than the thickness in the first regions 31 by printing.

It is preferred that the concentration of the insulator-forming solution is 10 percent by mass of solid content or more. If the solid content is set to be 10 percent by mass or more, the thickness of the insulator 4 can be made to be 1 μm or more.

In this manner, the insulator-forming solution filled all over the substrate 1 is hardened to form the insulator 4. To carry out hardening treatment, photosensitive polyimide resin is subjected to UV irradiation and thermosetting polyimide resin is subjected to heat-treatment. The heating temperature the time of hardening is 250° C. or less, preferably 220° C. or less. By setting the heating temperature as 250° C. or less, the insulator-forming solution can be hardened to form the insulator 4 formed from polyimide resin without giving a thermal damage to the existing pn junctions between the crystal semiconductor particles 2 and the semiconductor layer 3. Therefore, high-quality pn junction between the crystal semiconductor particles 2 and the semiconductor layer 3 can be maintained. It is preferred that hardening is carried out in nonoxidative atmosphere such as nitrogen or argon atmosphere. By carrying out heating and hardening treatment in such nonoxidative atmosphere, light transmittance of the insulator 4 and adhesive properties between the insulator 4 and the substrate 1 are improved.

The manufacturing method of this photovoltaic conversion device includes a process of forming the transparent conductive layer 5 so as to cover the upper part of the semiconductor particles 20 in the first regions 31 and at least the insulator 4 in the first regions 31.

The transparent conductive layer 5 can be formed by using a film-forming method such as sputtering and vapor growth, or coating and burning.

The manufacturing method of this photovoltaic conversion device includes a process of forming the collecting electrode comprised of the bus bar electrodes 16 disposed in the second regions 32 and the finger electrodes 15 disposed on the transparent conductive layer 5 so as to extend from the bus bar electrode 16 toward the first region 31.

Although the finger electrodes 15 are arranged on the conductive layer 5 over the whole surface of the first regions 31 and connected to the bus bar electrode 16, the arrangement method of the finger electrodes 15 can be designed appropriately.

The bus bar electrodes 16 are arranged and formed in the second regions 32. As in the photovoltaic conversion device shown in FIG. 1(b), the bus bar electrodes 16 may be formed on the transparent conductive layer 5 after forming of the transparent conductive layer 5 on the insulator 4. Alternatively, the bus bar electrodes 16 may be formed so as to make a direct contact with the insulator 4 without forming of the transparent conductive layer 5.

When the bus bar electrodes 16 are formed so as to make a direct contact with the insulator 4 without forming the transparent conductive layer 5, the transparent conductive layer 5 is formed so as to cover the insulator 4 in the regions other than the second regions 32 and the upper part of the semiconductor particles 20 by using a metal mask or the like. Subsequently, the finger electrodes 15 are arranged directly on the insulator 4 in the second regions 32 where the transparent conductive layer 5 is not formed.

When a protection layer (not shown) is formed on the transparent conductive layer 5 on which the bus bar electrodes 16 and the finger electrodes 15 are formed, a method such as CVD method, PVD method, etc. can be employed. The protection layer thus formed has characteristics of the transparent dielectric.

By forming the collecting electrode comprised of the finger electrodes 15 and the bus bar electrodes 16 in this manner, the photovoltaic conversion device can be produced.

According to this manufacturing method, the insulator 4 can be formed by filling the insulator-forming solution between semiconductor particles 20 without coating the semiconductor particles 20 with the insulator-forming solution. As a result, it becomes possible to prevent the quantity of the light led to the pn junctions from decreasing and therefore to readily produce the photovoltaic conversion device having high photovoltaic conversion efficiency.

FIG. 2 is a principal part sectional view showing a photovoltaic conversion device in accordance with another embodiment of the present invention.

The photovoltaic conversion device 1 in FIG. 2 has the substantially same configuration as that shown in FIG. 1(b). As shown in FIG. 2, a difference lies in that a conductive protection layer 7 is formed on the surface of the semiconductor particles 20.

The conductive protection layer 7 is formed from one or plural types of oxide films selected from SnO₂, In₂O₃, Indium Tin Oxide (ITO), ZnO, TiO₂ and the like or from one or plural types of metal films selected from titanium, platinum, gold and the like.

The conductive protection layer 7 is made from a material with high light transmittance having a wavelength of 400 to 1200 nm so as not to absorb light. Preferably, the light transmittance is 70% or more and ITO can be employed as such material. When the light transmittance of the conductive protection layer 7 falls between the above-mentioned range, loss in the amount of the light led to the pn junctions of the semiconductor particles 20 can be reduced.

The conductive protection layer 7 is formed on the surface of the semiconductor particles 20 except the junctions between the semiconductor particles 20 and the substrate 1, for example. Here, it is preferred that the conductive protection layer 7 is separated from the substrate 1. This contributes to preventing a short-circuit current that flows from the transparent conductive layer 5 to the substrate 1 through the conductive protection layer 7.

By providing the conductive protection layer 7 on the surface of the semiconductor particles 20 in this manner, photocurrents generated in the portion away from the portion that makes contact with the transparent conductive layer 5 of the semiconductor particles 20, for example, in the lower part of the semiconductor particles 20 can be transmitted to the transparent conductive layer 5 through the conductive protection layer 7 with little resistance. Accordingly, loss in the photocurrents generated within the semiconductor particles 20 can be reduced.

In addition, since the light which passes through insulator 4 is reflected on the substrate 1 and irradiated to the pn junctions of the semiconductor particles 20, the light entering into the whole of the photovoltaic conversion device can be efficiently irradiated to the pn junctions of the semiconductor particles 20. For this reason, efficient photovoltaic conversion can be achieved and moreover, resistance loss can be reduced since the generated photocurrents pass through the conductive protection layer 7.

The conductive protection layer 7 only needs to cover the semiconductor layer 3 which touch the insulator 4 and make contact with a part of the transparent conductive layer 5. That is, the conductive protection layer 7 may be formed all over the surface of the semiconductor particles 20 except the junctions between the crystal semiconductor particles 2 and the substrate 1 or the conductive protection layer 7 need not be formed on part of the surface of the semiconductor particles 20.

Like the transparent conductive layer 5, the conductive protection layer 7 is formed by using a film-forming method such as sputtering and vapor growth or coating and burning.

The conductive protection layer 7 is formed after joining between the semiconductor particles 20 and the substrate 1. In other words, the conductive protection layer 7 is formed in a period from joining between the semiconductor particles 20 and the substrate 1 and formation of the insulator 4. By forming the conductive protection layer 7 after joining the semiconductor particles 20 to the substrate 1, the semiconductor layer 3 and the conductive protection layer 7 can be formed also in the surface by the lower half part of the crystal semiconductor particles 2. By forming the conductive protection layer 7 on the semiconductor layer 3 prior to formation of the insulator 4, the pn junctions can be protected from damage due to heating during hardening treatment of the insulator 4 and atmosphere of oxygen and the like. This enables manufacturing of the photovoltaic conversion device with high photovoltaic conversion efficiency.

Next, another manufacturing method of the photovoltaic conversion device of the present invention will be described with reference to the photovoltaic conversion device shown in FIG. 2.

The manufacturing method of this photovoltaic conversion device has a process of forming the conductive protection layer 7 on the surface of the semiconductor particles 20 following the process of joining the semiconductor particles 20 to the substrate 1.

Similarly to the above-mentioned manufacturing method of the photovoltaic conversion device, firstly, the crystal semiconductor particles 2 are joined to the substrate 1 in the first regions 31 and the semiconductor layer 3 is formed on the surface of the crystal semiconductor particles 2 except the junctions between the crystal semiconductor particles 2 and the substrate 1 to produce the semiconductor particles 20.

Next, the conductive protection layer 7 is formed in the surface of the semiconductor particles 20 except the junctions between the semiconductor particles 20 thus prepared and the substrate 1 with being separated with the substrate 1. To separate the conductive protection layer 7 from the substrate 1, when the conductive protection layer 7 is formed, a portion where the conductive protection layer 7 is not formed may be provided in the perimeter of the junctions between the substrate 1 and the crystal semiconductor particles 2 with a mask. Alternatively, after the conductive protection layer 7 is formed all over the surface of the semiconductor particles 20, the conductive protection layer 7 in the vicinity of the junctions between the conductive protection layer 7 and the substrate 1 may be removed by etching.

Next, similarly to the above-mentioned manufacturing method, this photovoltaic conversion device can be produced by forming the insulator 4, the transparent conductive layer 5, the finger electrodes 15 and the bus bar electrodes 16.

When generated power of this photovoltaic conversion device is supplied to a load (not shown) using the above-mentioned photovoltaic conversion device, a solar energy system with high photovoltaic conversion efficiency can be obtained.

### EXAMPLES

Next, a first example of the photovoltaic conversion device of the present invention will be described with reference to the photovoltaic conversion device shown in FIG. 1(a) and FIG. 1(b).

A lot of crystal semiconductor particles 2 as p-type silicon having a particle diameter ranging from 0.3 to 0.5 mm were placed on the substrate 1 made from aluminum in the first regions 31. Subsequently, the crystal semiconductor particles 2 were fixed by applying a certain amount of weight from above and heated in N₂—H₂ mixture atmosphere at 630° C. for 10 minutes in the fixed state. In this manner, the substrate 1 was joined to the crystal semiconductor particles 2 via the alloy layer 10 of the substrate 1 and the crystal semiconductor particles 2.

Subsequently, to clean the surface of the crystal semiconductor particles 2, the substrate 1 to which the crystal semiconductor particles 2 are joined was immersed in a mixed solution of hydrofluoric acid-nitric acid having a weight ratio of hydrofluoric acid to nitric acid of 0.05 for one minute and washed with pure water adequately. Next, the semiconductor layer 3 made from n-type amorphous silicon was formed on the surface of the crystal semiconductor particles 2 except for a part thereof so as to have a thickness of 20 nm according to a plasma CVD method using the mixed gas of silane gas and a small amount of phosphorus compound.

Subsequently, polyimide resin having hardening temperature of 230° C. was melted in a N-methylpyrolidone solution to produce a polyimide solution as the insulator-forming solution. The concentration of the polyimide solution was 12 percent by mass and the viscosity at 25° C. was 40 mpa-s. The polyimide solution was supplied to the second regions 32 by using a dispenser and filled into the lower part between the semiconductor particles 20 on the substrate 1 in the first regions 31 so as to go away from the second region 32 according to the method using capillarity. The polyimide solution was formed thicker in the second regions 32 to which the polyimide solution was supplied firstly than in the first region 31. Subsequently, the polyimide solution was heated at 250° C. in a nitrogen atmosphere for one hour for hardening to form the insulator 4. The thickness of the insulator 4 was 10 μm in the second regions 32 and 3 μm in the center position between one adjoining part and the other adjoining part of the first region 31.

Next, the substrate 1 on which the insulator 4 was formed was supplied to a DC sputtering system using ITO as a target and the transparent conductive layer 5 made from ITO was formed in a thickness of 100 nm so as to cover the insulator 4 and the upper part of the semiconductor particles 20.

Subsequently, the finger electrodes 15 were formed on the transparent conductive layer 5 in the first regions 31 with silver paste, and the bus bar electrode 16 was formed on the transparent conductive layer 5 on the insulator 4 in the second regions 32 with silver paste. The photovoltaic conversion device was produced by forming the collecting electrode comprised of the finger electrodes 15 and the bus bar electrodes 16.

As a result of measurement of the photovoltaic conversion rate of the produced photovoltaic conversion device, the efficiency was found to be 8.3%. Further, heat cycle test from −40 to 90° C. with respect to the produced photovoltaic conversion device was performed up to 500 cycles and then each part of the photovoltaic conversion device was observed. Neither a crack nor peeling was generated in the insulator 4. As a result of measurement of the photovoltaic conversion rate of the produced photovoltaic conversion device after the heat cycle test, the efficiency was found to be 8.1%.

Next, a second example of the photovoltaic conversion device of the present invention will be described taking the photovoltaic conversion device shown in FIG. 2 as an example.

As in the first example, the crystal semiconductor particles 2 were joined to the substrate 1 to form the semiconductor layer 3. Next, the substrate 1 on which the semiconductor layer 3 was formed was supplied to a DC sputtering system using ITO as a target and the conductive protection layer 7 made from ITO was formed on the top part of the surface of the semiconductor layer 3. The thickness of the semiconductor particle 20 in the top part of the semiconductor layer 3 was 10 nm. Here, the top part means the highest position of the semiconductor particle 20.

After that, as in the first example, the insulator 4, the transparent conductive layer 5, the finger electrodes 15 and the bus bar electrodes 16 were formed to produce the photovoltaic conversion device. Also in the second example, as in the first example, the insulator 4 was formed to be thicker in the second region 32 to which the polyimide solution was applied firstly than in the first region 31. As a result of measurement of the photovoltaic conversion rate of the produced photovoltaic conversion device, the efficiency was found to be 8.5%. Further, a heat cycle test from −40 to 90° C. with respect to the produced photovoltaic conversion device was performed up to 500 cycles. Then, measurement of the photovoltaic conversion rate of this produced photovoltaic conversion device revealed that the efficiency was 8.4%.

In both of the first example and the second example, the photovoltaic conversion device having high photovoltaic conversion efficiency and high reliability was obtained. It is guessed that the reason why the photovoltaic conversion device having high photovoltaic conversion efficiency and high reliability was obtained was because short-circuit between the transparent conductive layer 5 and the substrate 1 can be prevented for sure even if photocurrents concentrate on the bus bar electrode 16, by forming the insulator 4 to be thicker in the second region 32 than in the first region 31. The photovoltaic conversion efficiency in the second example was higher than that in the first example. It is guessed that this was because resistance to photocurrents in a path from the place at which the photocurrents to the transparent conductive layer 5 was reduced by forming the conductive protection layer 7 on the surface of the semiconductor layer 3, resulting in reduction in resistance loss of the generated photocurrents.

As apparent from the above-mentioned results, since a short-circuit between the transparent conductive layer 5 and the substrate 1 was prevented for sure by forming the insulator 4 in the second regions 32 to be thicker than that in the first regions 31, the photovoltaic conversion device having high photovoltaic conversion efficiency could be obtained. Moreover, since the resistance loss of the generated photocurrent was reduced by forming the conductive protection layer 7 on the surface of the semiconductor layer 3, the photovoltaic conversion device having higher photovoltaic conversion efficiency could be obtained.

1. A photovoltaic conversion device comprising:
a substrate as a lower electrode having a first region and a second region adjacent to the first region;
a lot of semiconductor particles joined to the first region;
an insulator formed between the semiconductor particles on the substrate in the first region and on the substrate in the second region;
a transparent conductive layer as an upper electrode formed so as to cover the upper part of the semiconductor particles in the first region and the insulator in the first region; and
a collecting electrode formed of a finger electrode arranged on the transparent conductive layer in the first region and a bus bar electrode which is arranged in the second region and connected to the finger electrode, wherein
the thickness of the insulator in the second region is substantially larger than that of the insulator in the first region.

2. A photovoltaic conversion device as stated in claim 1 further comprising a conductive protection layer formed in the surface of the semiconductor particles.

3. A photovoltaic conversion device as stated in claim 1, wherein the insulator in the first region becomes thinner as the insulator is away from the second region.

4. A photovoltaic conversion device as stated in claim 1, wherein the second region is adjacent to both sides of the first region, the insulator has a curved surface that becomes depressed substantially in the shape of a concave in the upper part thereof and the most depressed portion of the curved surface is located at the center between a one side adjoining part where the first region is adjacent to one second region and an other side adjoining part where the first region is adjacent to the other second region.

5. A photovoltaic conversion device as stated in claim 1, wherein the thickness of the insulator in the first region is 1 μm or more in the thinnest portion.

6. A photovoltaic conversion device as stated in claim 1, wherein the thickness of the insulator in the second region is 5 μm or more.

7. A photovoltaic conversion device as stated in claim 2, wherein the conductive protection layer is formed from a material with an optical transmittance of 70% or more ranging from 400 to 1200 nm of wavelength.

8. A photovoltaic conversion device as stated in claim 2, wherein the conductive protection layer runs along the convex curved surface of the semiconductor particles.

9. A photovoltaic conversion device as stated in claim 1, wherein the insulator is made of polyimide resin.

10. A manufacturing method of a photovoltaic conversion device comprising steps of: preparing a substrate as a lower electrode having a first region and a second region adjacent to the first region and joining a lot of semiconductor particles to the substrate in the first region;
forming an insulator between the semiconductor particles on the substrate in the first region and on the substrate in the second region;
forming a transparent conductive layer as an upper electrode formed so as to cover the upper part of the semiconductor particles in the first region and the insulator in the first region; and
forming a finger electrode on the transparent conductive layer in the first region and a bus bar electrode connected to the finger electrode in the second region,
wherein in the step of forming the insulator, the thickness of the insulator in the first region is smaller than that of the insulator in the second region.

11. A manufacturing method of a photovoltaic conversion device as stated in claim 10 further comprising a step of forming a conductive protection layer formed on the surface of the semiconductor particles following the step of joining the semiconductor particles.

12. A manufacturing method of a photovoltaic conversion device as stated in claim 10, wherein in the step of joining the semiconductor particles, the substrate and the semiconductor particles are heated while a certain amount of weight is applied to the semiconductor particles.

13. A manufacturing method of a photovoltaic conversion device as stated in claim 10, wherein in the step of forming the insulator, the insulator is formed by using an insulator-forming solution with a concentration of solid content of 10 percent or more by mass.

14. A solar energy system using the photovoltaic conversion device as a power generating means as stated in claim 1 which is configured so as to supply electric power generated by the power generating means to a load.
